(19) United States
(12) Patent Application Publication
(10) Pub. No.: US 2013/0241641 A1
(43) Pub. Date: Sep. 19, 2013

(54) SIGNAL AMPLIFIER CIRCUIT FOR USB PORT

(71) Applicants: ZHI-MING ZHU, Wuhan (CN); TING WANG, Wuhan (CN)

(72) Inventors: ZHI-MING ZHU, Wuhan (CN); TING WANG, Wuhan (CN)

(21) Appl. No.: 13/678,679

(22) Filed: Nov. 16, 2012

(30) Foreign Application Priority Data
Mar. 16, 2012 (CN) 201210070036.8

(51) Int. Cl. H03F 3/45; H03F 3/68

(52) U.S. Cl. CPC H03F 3/45; H03F 3/68
USPC 330/124 R

(57) ABSTRACT

A signal amplifier circuit for USB port includes a USB controller, an amplifier circuit and a USB port. The USB controller includes a super speed transmitter differential pair and a super speed receiver differential pair. The amplifier circuit includes two first input terminals, two second input terminals, two first output terminals, and two second output terminals. The USB port includes two first differential signal receiving terminals and two first differential signal transmitting terminals. The super speed transmitter differential pair and the super speed receiver differential pair are electrically connected to the first input terminals and the second output terminals. The first output terminals and the second input terminals are electrically connected to the first differential signal receiving terminals and the first differential signal transmitting terminals. The amplifier circuit amplifies differential signals transmitted between the USB controller and the USB port.

### BACKGROUND

1. Technical Field

The present disclosure relates to a signal amplifier circuit for USB ports.

2. Description of Related Art

Universal serial bus (USB) technology is broadly applied as a solution to serial communications. The USB 3.0 specification was published on Nov. 12, 2008. The USB 3.0 specification's main goals were to increase the data transfer rate (up to 5 Gbit/s), to decrease power consumption, to increase power output, and to be backwards-compatible with USB 2.0. USB 3.0 includes a new, higher speed bus called super speed in parallel with the USB 2.0 bus. The signals usually tend to attenuate in USB 3.0 during transmission for a long distance on printed circuit boards. Therefore, the quality of the signals is affected.

Therefore there is a need for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of an embodiment of a signal amplifier circuit for USB port.

FIG. 2 is a circuit diagram of the signal amplifier circuit of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

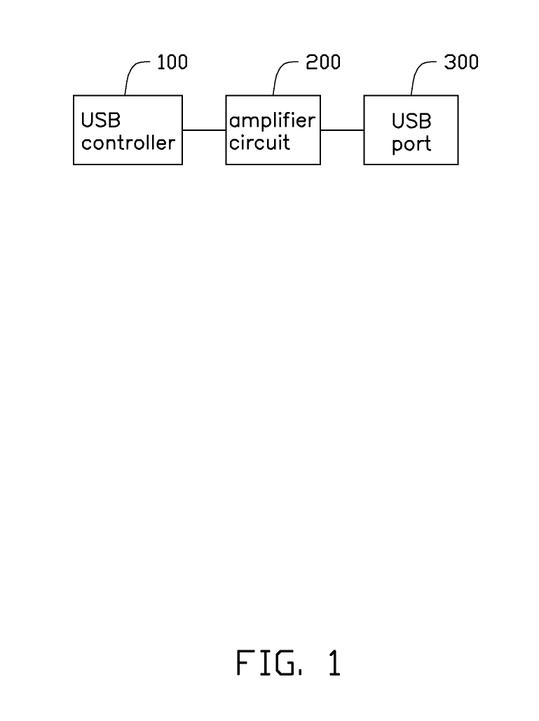

FIG. 1 illustrates a block diagram of a signal amplifier circuit for USB ports in accordance with one embodiment. The signal amplifier circuit includes a USB controller 100, an amplifier circuit 200, and a USB port 300. The amplifier circuit 200 amplifies differential signals transmitted between the USB controller 100 and the USB port 300. In one embodiment, the USB port 300 is a USB 3.0 port.

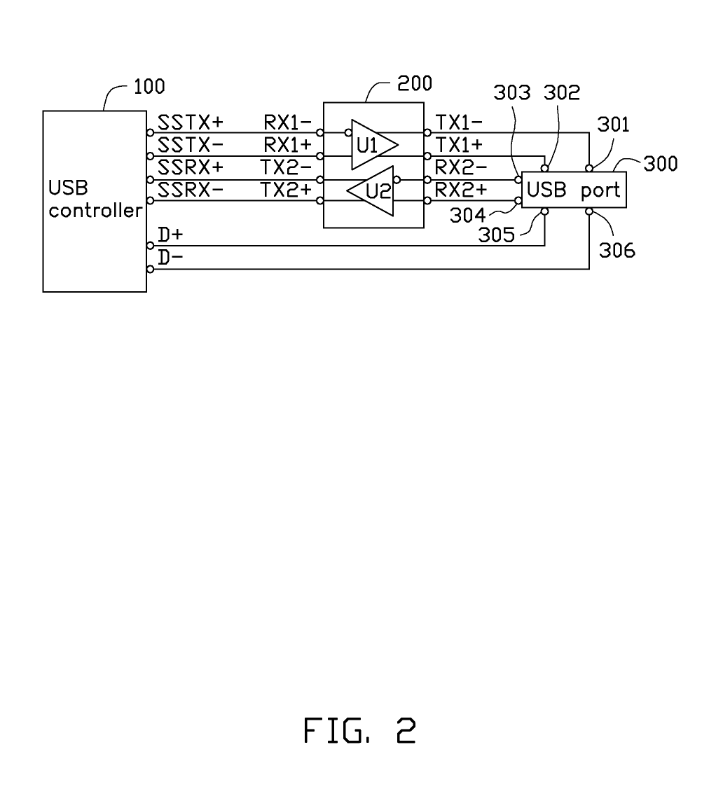

FIG. 2 illustrates a circuit diagram of the signal amplifier circuit in accordance with one embodiment. The USB controller 100 includes a super speed transmitter differential pair SSTX+, SSTX−, a super speed receiver differential pair SSRX+, SSRX−, and two first differential signal receiving and transmitting terminals D+, D−. The amplifier circuit 200 includes two first input terminals RX1+, RX1−, two second input terminals RX2+, RX2−, two first output terminals TX1+, TX1−, and two second output terminals TX2+, TX2−. The USB port 300 includes two first differential signal receiving terminals 301, 302, two first differential signal transmitting terminals 303, 304, and two second differential signal receiving and transmitting terminals 305, 306. The super speed transmitter differential pair SSTX+, SSTX− are electrically connected to the first input terminals RX1−, RX1+. The super speed receiver differential pair SSRX+, SSRX− are electrically connected to the second output terminals TX2−, TX2+. The first output terminals TX1−, TX1+ are electrically connected to the first differential signal receiving terminals 301, 302. The second input terminals RX2−, RX2+ are electrically connected to the first differential signal transmitting terminals 303, 304. The first differential signal receiving and transmitting terminals D+, D− are electrically connected to the second differential signal receiving and transmitting terminals 305, 306.

The amplifier circuit 200 includes a first amplifier U1 and a second amplifier U2. The first amplifier U1 is electrically connected to the first input terminals RX1−, RX1+ and the first output terminals TX1−, TX1+. The second amplifier U2 is electrically connected to the second input terminals RX2−, RX2+ and the second output terminals TX2−, TX2+. In one embodiment, the first differential signal receiving and transmitting terminals D+, D− and the second differential signal receiving and transmitting terminals 305, 306 support the USB 2.0 specification. The super speed transmitter differential pair SSTX+, SSTX− and the super speed receiver differential pair SSRX+, SSRX− support the USB 3.0 specification.

In operation, the data of USB 3.0 specification stored in the USB controller 100 is transmitted to the first amplifier U1 from the super speed transmitter differential pair SSTX+, SSTX− to the first input terminals RX1−, RX1+. The data of USB 3.0 is amplified by the first amplifier U1 and is then transmitted to the USB port 300 from the first output terminals TX1−, TX1+ to the first differential signal receiving terminals 301, 302. The data of USB 3.0 specification from the USB port 300 is transmitted to the second amplifier U2 via the second input terminals RX2−, RX2+. The data of USB 3.0 is amplified by the second amplifier U2 and is then transmitted to the USB controller 100 from the second output terminals TX2−, TX2+ to the super speed receiver differential pair SSRX+, SSRX−. The data of USB 2.0 specification stored in the USB controller 100 is transmitted to the USB port 300 from the first differential signal receiving and transmitting terminals D+, D− to the second differential signal receiving and transmitting terminals 305, 306. The data of USB 2.0 specification from the USB port 300 is transmitted to the USB controller 100 via the second differential signal receiving and transmitting terminals 305, 306 to the first differential signal receiving and transmitting terminals D+, D−.

Even though numerous characteristics and advantages of the present disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A signal amplifier circuit for USB port comprising:
a USB controller comprising a super speed transmitter differential pair and a super speed receiver differential pair;
an amplifier circuit comprising two first input terminals, two second input terminals, two first output terminals, and two second output terminals; and
a USB port comprising two first differential signal receiving terminals and two first differential signal transmitting terminals; wherein the super speed transmitter differential pair and the super speed receiver differential pair are electrically connected to the two first input terminals and the two second output terminals, respectively; the two first output terminals and the two second input terminals are electrically connected to the two first differential signal receiving terminals and the two first differential signal transmitting terminals, respectively; and the amplifier circuit is adapted to amplify differential signals transmitted between the USB controller and the USB port.

2. The signal amplifier circuit of claim 1, wherein the amplifier circuit further comprises a first amplifier and a second amplifier; the first amplifier is electrically connected to the two first input terminals and the two first output terminals; and the second amplifier is electrically connected to the two second input terminals and the two second output terminals.

3. The signal amplifier circuit of claim 2, wherein the super speed transmitter differential pair comprises a super speed transmitter positive differential terminal and a super speed transmitter negative differential terminal; and the super speed receiver differential pair comprises a super speed receiver positive differential terminal and a super speed receiver negative differential terminal

4. The signal amplifier circuit of claim 3, wherein the USB controller further comprises two first differential signal receiving and transmitting terminals; the USB port further comprises two second differential signal receiving and transmitting terminals; and each of the two first differential signal receiving and transmitting terminals is electrically connected to each of the two second differential signal receiving and transmitting terminals.

5. The signal amplifier circuit of claim 4, wherein each of the two first differential signal receiving and transmitting terminals comprises a first differential signal receiving and transmitting positive terminal and a first differential signal receiving and transmitting negative terminal; and each of the two second differential signal receiving and transmitting terminals comprises a second differential signal receiving and transmitting positive terminal and a second differential signal receiving and transmitting negative terminal

6. The signal amplifier circuit of claim 4, wherein the two first differential signal receiving and transmitting terminals and the two second differential signal receiving and transmitting terminals support USB 2.0 specification.

7. The signal amplifier circuit of claim 1, wherein the super speed transmitter differential pair and the super speed receiver differential pair support USB 3.0 specification.

8. A signal amplifier circuit for USB port comprising:
a USB controller comprising a super speed transmitter differential pair and a super speed receiver differential pair;
an amplifier circuit comprising a first amplifier, a second amplifier, two first input terminals, two second input terminals, two first output terminals, and two second output terminals; wherein the first amplifier is electrically connected to the two first input terminals and the two first output terminals; and the second amplifier is electrically connected to the two second input terminals and the two second output terminals; and
a USB port comprising two first differential signal receiving terminals and two first differential signal transmitting terminals; wherein the super speed transmitter differential pair and the super speed receiver differential pair are electrically connected to the two first input terminals and the two second output terminals, respectively; the two first output terminals and the two second input terminals are electrically connected to the two first differential signal receiving terminals and the two first differential signal transmitting terminals, respectively; and the amplifier circuit is adapted to amplify differential signals transmitted between the USB controller and the USB port.

9. The signal amplifier circuit of claim 8, wherein the super speed transmitter differential pair comprises a super speed transmitter positive differential terminal and a super speed transmitter negative differential terminal; and the super speed receiver differential pair comprises a super speed receiver positive differential terminal and a super speed receiver negative differential terminal

10. The signal amplifier circuit of claim 9, wherein the USB controller further comprises two first differential signal receiving and transmitting terminals; the USB port further comprises two second differential signal receiving and transmitting terminals; and
each of the two first differential signal receiving and transmitting terminals is electrically connected to each of the two second differential signal receiving and transmitting terminals.

11. The signal amplifier circuit of claim 10, wherein each of the two first differential signal receiving and transmitting terminals comprises a first differential signal receiving and transmitting positive terminal and a first differential signal receiving and transmitting negative terminal; and each of the two second differential signal receiving and transmitting terminals comprises a second differential signal receiving and transmitting positive terminal and a second differential signal receiving and transmitting negative terminal

12. The signal amplifier circuit of claim 10, wherein the two first differential signal receiving and transmitting terminals and the two second differential signal receiving and transmitting terminals support USB 2.0 specification.

13. The signal amplifier circuit of claim 8, wherein the super speed transmitter differential pair and the super speed receiver differential pair support USB 3.0 specification.
